(19) United States
(12) Patent Application Publication
(10) Pub. No.: US 2019/0045632 A1
(43) Pub. Date: Feb. 7, 2019

(54) CONNECTOR, BOARD ASSEMBLY, COMPUTING SYSTEM, AND METHODS THEREOF

(71) Applicant: Intel Corporation, Santa Clara, CA (US)

(72) Inventors: Xiang Li, Portland, OR (US); Jun Liao, Hillsboro, OR (US); Yunhui CHU, Hillsboro, OR (US); George Vergis, Portland, OR (US); Chong Zhao, West Linn, OR (US)

(21) Appl. No.: 16/051,573

(22) Filed: Aug. 1, 2018

(51) Int. Cl. H05K 1/14; H01R 12/52; H01R 12/73; H01R 13/17

(52) U.S. Cl. CPC H05K 1/142; H01R 13/17; H01R 12/732; H01R 12/52

(57) ABSTRACT

Various aspects are related to a connector, e.g., for connecting two boards with one another. The connector may include a housing and a plurality of pins. The housing may include a first housing surface and a second housing surface opposite the first housing surface. Each pin of the plurality of pins may include a first portion protruding arcuately from the first housing surface and a second portion protruding arcuately from the second housing surface.

### TECHNICAL FIELD

Various aspects relate generally to a connector, a board assembly, computing system, and methods thereof, e.g., a method for mounting a board assembly.

### BACKGROUND

In some applications, a modular hardware system may be implemented to set up a computing system efficiently in accordance with various desired functionalities, or a desired performance. In general, a computer system may include a main board (also referred to as a motherboard, a system board, or a logic board) and various possibilities to connect additional boards (also referred to as cards, or modules) to the main board. Further, there may be the possibility to expand a functionality or a performance of a suitable carrier board by mounting an additional board (also referred as a mezzanine board, a daughterboard, a piggyback board, or a riser board) to the carrier board and by connecting (e.g., communicatively coupling) the additional board to the carrier board. A carrier board that provides the possibility of hosting an additional board may be referred to as a mezzanine carrier board and the additional board that can be mounted, at the mezzanine carrier board, may be referred to as a mezzanine board. In general, a board may be also referred to as a card. For example, a mezzanine board may be also referred to as a mezzanine card, whereas a carrier board may be also referred to as a carrier card.

### BRIEF DESCRIPTION OF THE DRAWINGS

Throughout the drawings, it should be noted that like reference numbers are used to depict the same or similar elements, features, and structures. The drawings are not necessarily to scale, emphasis instead generally being placed upon illustrating aspects of the disclosure. In the following description, some aspects of the disclosure are described with reference to the following drawings, in which:

FIG. 1A, FIG. 1B, and FIG. 1C show a connector in various schematic views, according to various aspects;

FIG. 2 shows a pin of a connector in a schematic view, according to some aspects;

FIG. 3A, FIG. 3B, and FIG. 3C show a connector in a various schematic views, according to various aspects;

FIG. 4 shows a crosstalk characteristic of a connector, according to some aspects;

FIG. 5 shows a Time Domain Reflectometry characteristic of a connector, according to some aspects;

FIG. 6 shows an exemplary memory module associated with at least one connector in a schematic view, according to various aspects;

FIG. 7 shows an exemplary pin layout of a connector in a schematic view, according to various aspects;

FIG. 8 shows a flow diagram of a method for mounting a board assembly, according to various aspects;

FIG. 9 shows an exemplary board assembly including a connector in a schematic view, according to various aspects; and

FIG. 10 shows an exemplary computing system including a board assembly with a connector in a schematic view, according to various aspects.

### DETAILED DESCRIPTION

The following detailed description refers to the accompanying drawings that show, by way of illustration, specific details and aspects in which the disclosure may be practiced. These aspects are described in sufficient detail to enable those skilled in the art to practice the disclosure. Other aspects may be utilized and structural, logical, and electrical changes may be made without departing from the scope of the disclosure. The various aspects are not necessarily mutually exclusive, as some aspects can be combined with one or more other aspects to form new aspects. Various aspects are described in connection with methods and various aspects are described in connection with devices. However, it may be understood that aspects described in connection with methods may similarly apply to the devices, and vice versa.

The word “exemplary” is used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The words “plural” and “multiple” in the description and the claims expressly refer to a quantity greater than one. Accordingly, any phrases explicitly invoking the aforementioned words (e.g., “a plurality of [objects],” “multiple [objects]”) referring to a quantity of objects expressly refers more than one of the said objects. The terms “group (of),” “set [of],” “collection (of),” “series (of),” “sequence (of),” “grouping (of),” among others, in the description and in the claims, if any, refer to a quantity equal to or greater than one, i.e. one or more.

The term “data” as used herein may be understood to include information in any suitable analog or digital form, e.g., provided as a file, a portion of a file, a set of files, a signal or stream, a portion of a signal or stream, a set of signals or streams, among others. Further, the term “data” may also be used to mean a reference to information, e.g., in form of a pointer. The term data, however, is not limited to the aforementioned examples and may take various forms and represent any information as understood in the art.

The terms “processor” or “controller” as, for example, used herein may be understood as any kind of entity that allows handling data. The data may be handled according to one or more specific functions executed by the processor or controller. Further, a processor or controller as used herein may be understood as any kind of circuit, e.g., any kind of analog or digital circuit. The term “handle” or “handling” as for example used herein referring to data handling, file handling or request handling may be understood as any kind of operation, e.g., an I/O operation, and/or any kind of logic operation. An I/O operation may include, for example, storing (also referred to as writing), and reading.

A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), among others, or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

Differences between software and hardware implemented data handling may blur. A processor, controller, and/or circuit detailed herein may be implemented in software, hardware and/or as hybrid implementation including software and hardware.

The term “system” (e.g., a computing system) detailed herein may be understood as a set of interacting elements, wherein the elements can be, by way of example and not of limitation, one or more mechanical components, one or more electrical components, one or more instructions (e.g., encoded in storage media), and/or one or more processors, among others.

The term “memory” detailed herein may be understood to include any suitable type of memory device (e.g., memory module). A memory module may, for instance, include one or more volatile memory modules and/or one or more non-volatile memory modules.

As used herein, the term “memory,” “memory module,” and the like may be understood as a non-transitory computer-readable medium in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, 3D crosspoint (3DXP), among others, or any combination thereof. Furthermore, it is appreciated that registers, shift registers, processor registers, data buffers, among others, are also embraced herein by the term memory. It is appreciated that a single component referred to as “memory” or “a memory module” may be composed of more than one different type of memory, and thus may refer to a collective component including one or more types of memory. It is readily understood that any single memory component may be separated into multiple collectively equivalent memory components, and vice versa. Furthermore, while memory may be depicted as separate from one or more other components (such as in the drawings), it is understood that memory may be integrated within another component, such as on a common integrated chip.

A volatile memory may be a storage medium that requires power to maintain the state of data stored by the medium. Non-limiting examples of volatile memory may include various types of RAM, such as dynamic random access memory (DRAM) or static random access memory (SRAM). One particular type of DRAM that may be used in a memory module is a synchronous dynamic random access memory (SDRAM). In some aspects, DRAM of a memory component may comply with a standard promulgated by Joint Electron Device Engineering Council (JEDEC), such as JESD79F for double data rate (DDR) SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4 (these standards are published). Such standards (and similar standards) may be referred to as DDR-based standards and communication interfaces of the storage devices that implement such standards may be referred to as DDR-based interfaces.

Various aspects may be applied to any memory module that includes non-volatile memory. In one aspect, the memory module may be a block addressable memory module, such as those based on negative-AND (NAND) logic or negative-OR (NOR) logic technologies. A memory may also include future generation non-volatile devices, such as a 3DXP memory module, or other byte addressable write-in-place non-volatile memory modules. A 3DXP memory may include a transistor-less stackable cross-point architecture in which memory cells sit at the intersection of word lines and bit lines and are individually addressable and in which bit storage is based on a change in bulk resistance.

According to various aspects, the term “volatile” and the term “non-volatile” may be used herein, for example, with reference to a memory, a memory cell, a memory module, a storage device, among others. These terms may be used to distinguish two different classes of (e.g., computer) memories. A volatile memory may be a memory (e.g., computer memory) that retains the information stored therein only while the memory is powered on, e.g., while the memory cells of the memory are supplied via a supply voltage. In other words, information stored on a volatile memory may be lost immediately or rapidly in the case that no power is provided to the respective memory cells of the volatile memory. A non-volatile memory, in contrast, may be a memory that retains the information stored therein while powered off In other words, data stored on a non-volatile memory may be preserved even in the case that no power is provided to the respective memory cells of the non-volatile memory. Illustratively, non-volatile memories may be used for a long-term persistent storage of information stored therein, e.g., over one or more years or more than ten years. However, non-volatile memory cells may also be programmed in such a manner that the non-volatile memory cell becomes a volatile memory cell (for example, by means of correspondingly short programming pulses or a correspondingly small energy budget introduced into the respective memory cell during programming).

In some aspects, the memory module may be or may include memory modules that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magneto resistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory module, or a combination of any of the above, or other memory. The terms memory or memory module may refer to the die itself and/or to a packaged memory product.

The term memory cell, as referred to herein, may be understood as a building block of a (e.g., computer) memory. The memory cell may be an electronic circuit configured to store one or more bits. The one or more bits may be associated to at least two voltage levels that can be set and read out (e.g., a logic 0, a logic 1, or in multi bit memory cells, a combination thereof). A plurality of memory cells of the same memory type may be addressable within a single electronic device, e.g., within a single memory module. Further, there may be hybrid electronic devices (e.g., memory modules) including a plurality of memory cells of the different memory types respectively.

Various aspects are related to a connector, e.g., for connecting two boards with one another. In some aspects, the connector may be a mezzanine connector to connect a mezzanine card (also referred to as mezzanine board) to a carrier card (also referred to as carrier board).

In general, a mezzanine card may be associated with various standards, e.g., a common mezzanine card (CMC) may be associated with the IEEE 1386 standard, a PCI (Peripheral Component Interconnect) Mezzanine Card (PMC) may be associate with the IEEE P1386.1 standard, among others. A carrier card may be associated with the standard Eurocard format including single, double, and triple-height VMEbus (Versa Module Eurocard-bus) cards, CompactPCI (cPCI) cards, VPX cards, among others. As an example, a standard 3U carrier card may host a single PMC and a standard 6U carrier card (e.g., using VMEbus) may host one or two PMCs.

Further, as an example, the VITA 20 standard may define a conduction-cooled PMC (CCPMC). The VITA 32 standard may define a processor PMC (PPMC, PrPMC). The VITA 39 standard may define a Peripheral Component Interconnect eXtended PMC (PCI-X PMC, PMC-X). The VITA 42 standard may define an XMC (also referred to as Switched Mezzanine Card), e.g., a PMC with high-speed serial fabric interconnect or other high speed serial formats, such as, for example, Serial RapidIO (VITA 42.2) and Parallel RapidIO (VITA 42.1). The VITA 57 (FMC) standard may define an FPGA (Field Programmable Gate Array) mezzanine card (FMC).

Some aspects are related to platforms demanding a high bandwidth for memory and I/O interfaces. Various aspects are related to a high density interconnect solution supporting high speed signaling.

The selection and design of a connector (e.g., board-to-board connector) may be based on a number of factors. In some aspects, a high-density mezzanine connector is provided having a plurality of pins embedded in a housing. A high-density mezzanine connector may have a Z-height of about 5 mm or more. In general, the high-density mezzanine connector may have a good signaling performance for differential input/output (I/O), but a reduced signaling performance for single ended signaling. Furthermore, manufacturing costs for a high-density mezzanine connector may prove cost-prohibitive (e.g., $20 USD or more) for certain applications.

According to various aspects, a connector is provided having a plurality of C-shaped pins embedded in a housing. This connector may be easy to manufacture at low costs. The design of the pin shape described herein keeps the connector at a low Z-height (e.g., below 2 mm) for better signaling performance. In summary, the connector described as follows may feature low cost manufacturing and a high pin density (i.e. tight pitch and array placement) in a high-speed interconnect solution.

According to various aspects, the connector may be used for a board-to-board connection, wherein both boards include an arrangement of contact pads for the electrical connection. The connector may be sandwiched between the two boards to be connected with one another. The connector may be configured to provide a spring-loaded electrical connection between the respective contact pads of the two boards.

According to various aspects, the pin of the connector may be built by stamping and the pin array may be adapted with respect to the pin layout, e.g., from application to application. The housing of the connector may be configured to hold the pins at a pre-defined position and may be manufactured via a mold process, e.g., by over molding. This may be an economic way to allow cost efficient high volume manufacturing.

In the following, a connector that may be used for board-to-board connection is described, according to various aspects. The connector may be used in any application implementing a high pin density (e.g., more than 50 pins per square centimeter) and high signaling performance (e.g., a high data rate (e.g., greater than about 5 Gbit/s), a low crosstalk (e.g., lower than −15 dB at a frequency of 9 GHz, lower than −30 dB at a frequency of 2 GHz, among others), among others).

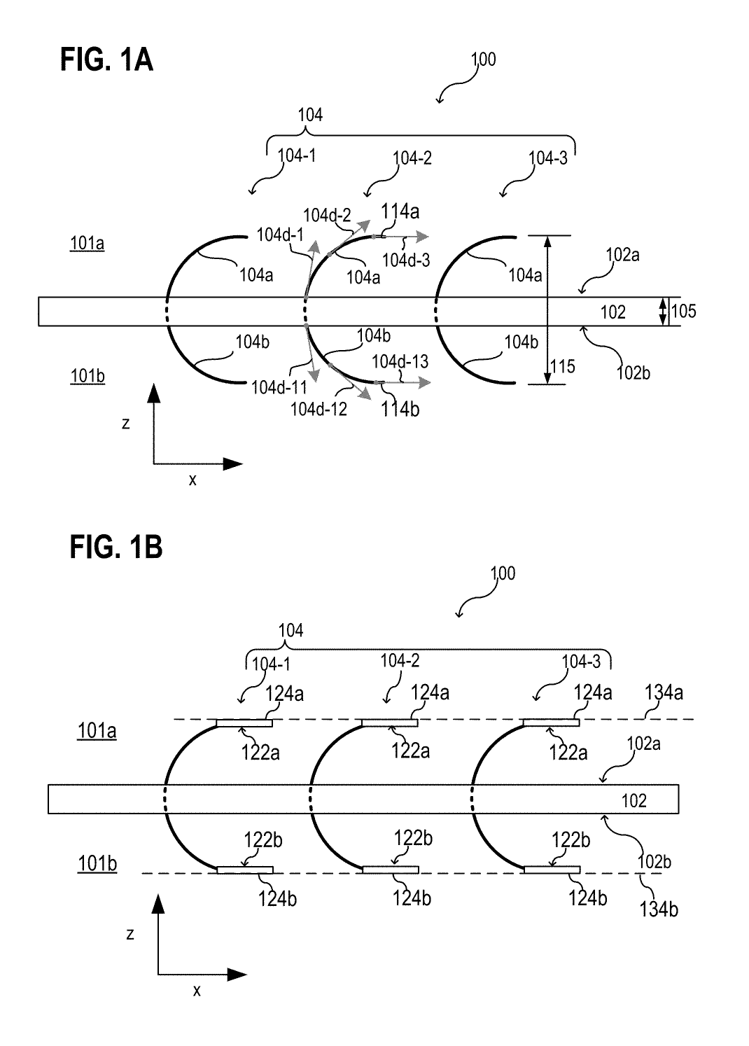

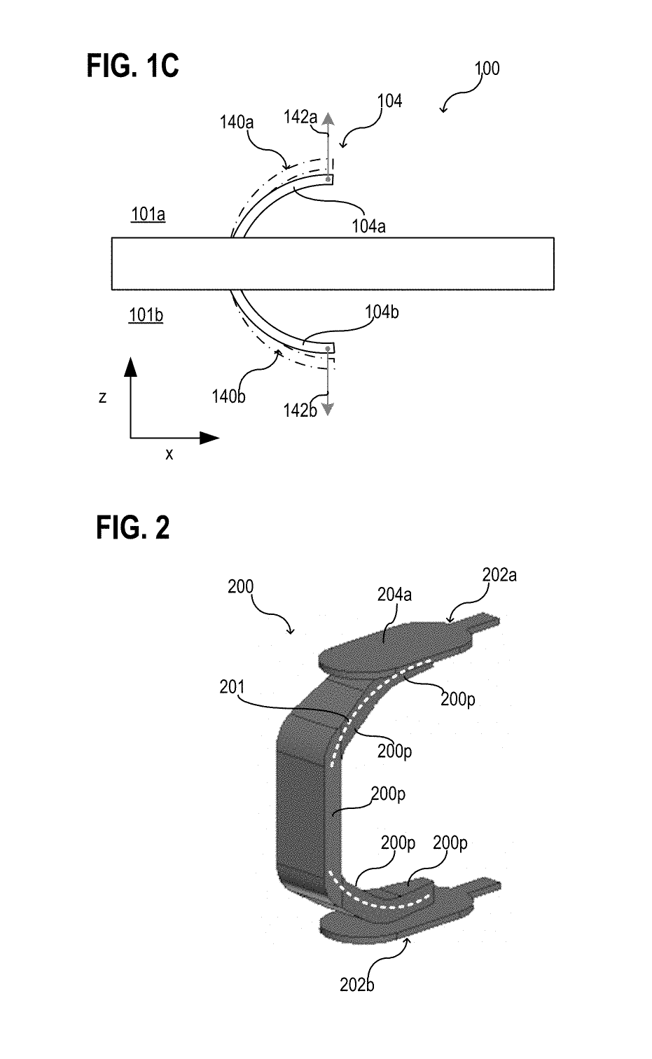

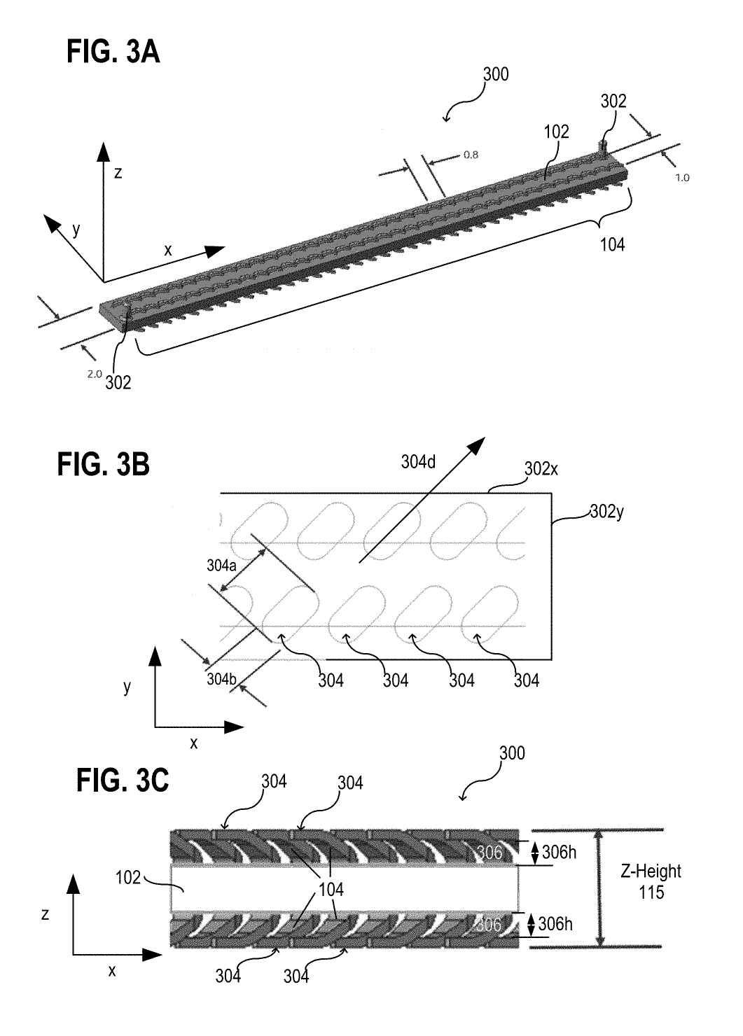

FIG. 1A illustrates exemplarily a connector 100 in a schematic side or cross-sectional view, according to various aspects. The connector 100 may include a housing 102 and a plurality of pins 104. The housing 102 may be configured to hold the pins 104 at predefined positions. The pins may be aligned regularly, e.g., having a fixed spacing in x-direction and/or a fixed spacing in y-direction (see FIG. 3A and FIG. 3B).

According to various aspects, the housing 102 may be configured to electrically isolate the pins 104 from one another, or, in other words, to avoid an electrically conductive connection from one pin of the plurality of pins 104 to another one. The housing 102 may include or may consist of any type of electrically insulating material, e.g., an electrically insulating mold material. The electrically insulating material may include a polymer or a mixture of more than one different types of polymers. The electrically insulating material may include for example one or more thermoplastic polymers, one or more thermosetting polymers, among others. In some aspects, the housing 102 may be formed by molding; however, any other suitable type of manufacturing may be used in a similar way.

According to various aspects, the housing 102 may have a bar-shape. As an example, the housing may include a first housing surface 102a at the first side 101a and second housing surface 102b at the second side 101b, wherein the first side 101a is opposite to the second side 101b. The first housing surface 102a and the second housing surface 102b may be parallel (or substantially parallel) to one another.

According to various aspects, a dimension (also referred to as z-height) 105 of the housing 102 perpendicular (or substantially perpendicular) to the first housing surface 102a and perpendicular (or substantially perpendicular) to the second housing surface 102b may be less than about 1 mm.

According to various aspects, each pin 104-1, 104-2, 104-3 of the plurality of pins 104 may extend from a first side 101a of the housing 102 through the housing 102 to a second side 101b of the housing 102. In some aspects, each of the pins 104 may be a monolithic piece. For example, each of the pins 104 may be integrally formed as a single piece via stamping or any other suitable method to provide a pin with the desired shape. The pins may include or consist of a metal, a metal alloy, or any other electrically conductive material. The metal may include copper, aluminum, among others. The metal alloy may include AlCu, among others.

According to various aspects, each pin 104-1, 104-2, 104-3 of the plurality of pins 104 may be arcuate (e.g., curved, and/or bent). A first portion 104a of the respective pin 104 may protrude arcuately from the housing 102 at the first side 101a and a second portion 104b of the respective pin 104 may protrude arcuately from the housing 102 at the second side 101b.

Illustratively, each pin of the plurality of pins 104 may include a first arcuate portion 104a that protrudes from the housing 102 (e.g., first housing surface 102a) at the first side 101a and a second arcuate portion 104b that protrudes from the housing 102 (e.g., second housing surface 102b) at the second side 101b. Illustratively, each of the pins 104 may be arch-shaped. The pins 104 may extend, or protrude along a curved line or along a polygonal chain (e.g., a polygonal chain having a shape similar to a curved line, among others). Illustratively, the pins 104 may be c-shaped (or substantially c-shaped), u-shaped (or substantially u-shaped), among others.

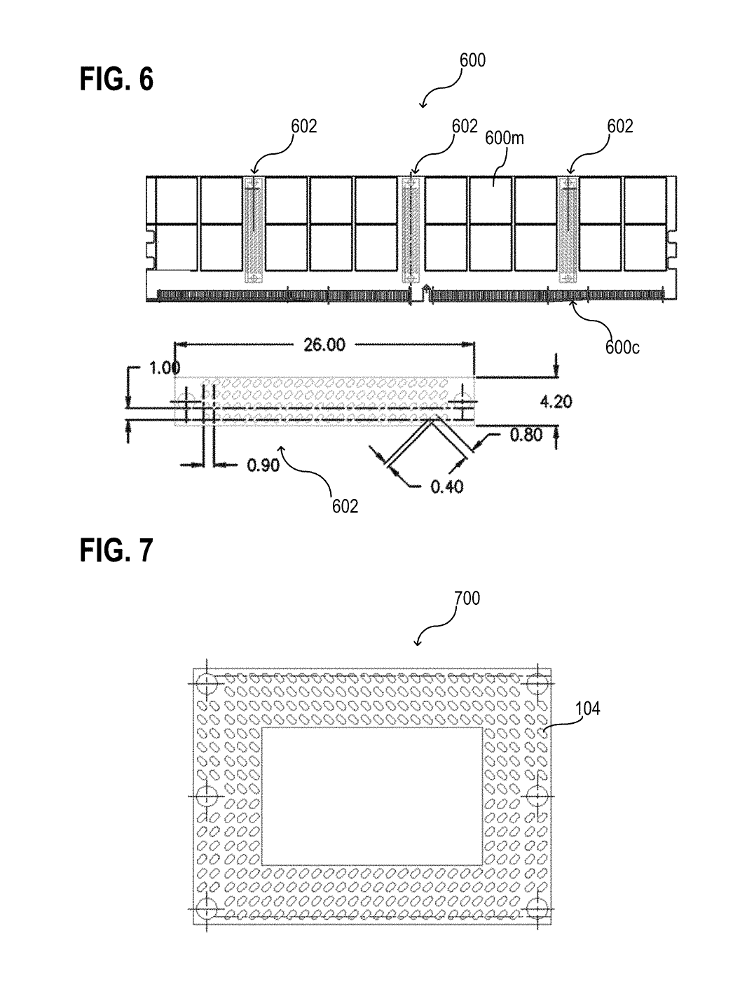

In some aspects, the shape of the pins 104 may define the electronic properties of the connector 100; see, for example, FIG. 6 that shows exemplarily a crosstalk behavior of the connector 100.

Further, the shape of the pins 104 may allow the manufacture of the connector 100 with a relative small height (also referred to as z-height) 115. The height 115 of the connector 100 may be defined by the height of the pins 104. In some aspects, the height 115 of the connector 100 and the pins 104 may be less than 2 mm. As a result, this configuration may allow achieving a low crosstalk between the pins 104.

According to some aspects, the first arcuate portion 104a of the respective pin 104 may be elongated into various (e.g., at least two, at least three, or more than three) different directions 104d-1, 104d-2, 104d-3. An end-portion 114a of the first arcuate portion 104a may be elongated parallel (or substantially parallel) to a first surface 102a of the housing 102. As an example, a first segment of the first arcuate portion 104a is elongated along a first direction 104d-1 and a second segment of the first arcuate portion 104a is elongated along a second direction 104d-2 different from the first direction. As another example, a first segment of the first arcuate portion 104a is elongated along a first direction 104d-1, a second segment of the first arcuate portion 104a is elongated along a second direction 104d-2 different from the first direction 104d-1, and a third segment of the first arcuate portion 104a is elongated along a third direction 104d-3 different from both the first direction 104d-1 and the second direction 104d-2.

According to some aspects, the second arcuate portion 104b of the respective pin 104 may be elongated into various (e.g., at least two, at least three, or more than three) different directions 104d-11, 104d-12, 104d-13. An end-portion 114b of the second arcuate portion 104b may be elongated parallel (or substantially parallel) to a second surface 102b of the housing 102. As an example, a first segment of the second arcuate portion 104b is elongated along a fourth direction 104d-11 and a second segment of the second arcuate portion 104b is elongated along a fifth direction 104d-12 different from the fourth direction. As another example, a first segment of the second arcuate portion 104b is elongated along a fourth direction 104d-11, a second segment of the second arcuate portion 104b is elongated along a fifth direction 104d-12 different from the fourth direction 104d-11, and a third segment of the second arcuate portion 104b is elongated along a sixth direction 104d-13 different from both the fourth direction 104d-11 and the fifth direction 104d-12.

According to various aspects, the first direction 104d-1 and the fourth direction 104d-11 may, in some aspects, represent the same angle with respect to the longitudinal axis of the housing 102. Alternatively, the first direction 104d-11 and the fourth direction 104d-11 may, in some aspects, represent different angles with respect to the longitudinal axis of the housing 102. According to various aspects, the second direction 104d-2 and the fifth direction 104d-12 may, in some aspects, represent the same angle with respect to the longitudinal axis of the housing 102. Alternatively, the second direction 104d-2 and the fifth direction 104d-12 may, in some aspects, represent different angles with respect to the longitudinal axis of the housing 102. According to various aspects, the third direction 104d-3 and the sixth direction 104d-13 may, in some aspects, represent the same angle with respect to the longitudinal axis of the housing 102. Alternatively, the third direction 104d-3 and the sixth direction 104d-13 may, in some aspects, represent different angles with respect to the longitudinal axis of the housing 102.

According to various aspects, each pin 104 of the connector 100 may extend along a curved line, wherein the curved line lies within a respective plane. The pins 104 of the connector 100 may be arranged and shape in such a way that all planes associated with the pins 104 are parallel (or substantially parallel) to one another. Illustratively, all pins of the plurality of pins 104 may be aligned in the same direction.

FIG. 1B illustrates exemplarily a connector 100 in a schematic side or cross-sectional view, according to various aspects. The connector 100 may include a housing 102 and a plurality of pins 104. The housing 102 and the pins 104 may be configured in the same or a similar way as described above with reference to FIG. 1A and vice versa.

As illustrated in FIG. 1B, each pin 104-1, 104-2, 104-3 of the plurality of pins 104 includes a first contact region 122a at the first side 101a and a second contact region 122b at the second side 101b. The first contact region 122a has a first contact surface 124a and the second contact region 122b has a second contact surface 124b. According to various aspects, the first contact surface 124a may face away from the first housing surface 102a and the second contact surface 124b may face away from the second housing surface 102b. Both the first contact surface 124a and the second contact surface 124b may have a planer shape.

According to various aspects, all first contact surfaces 124a of the plurality of pins 104 may be parallel (or substantially parallel) to one another. In some aspects, all first contact surfaces 124a of the plurality of pins 104 may lie in a first plane 134a. According to various aspects, all second contact surfaces 124b of the plurality of pins 104 may be parallel (or substantially parallel) to one another. In some aspects, all second contact surfaces 124b of the plurality of pins 104 may lie in a second plane 134b. In some aspect, the first plane 134a and the second plane 134b are parallel (or substantially parallel) to one another. In some aspects, the first plane 134a may be parallel (or substantially parallel) to the first housing surface 102a and the second plane 134b may be parallel (or substantially parallel) to the second housing surface 102b.

FIG. 1C illustrates exemplarily a pin 104 of the connector 100 in a more detailed view, according to various aspects. According to various aspects, the first arcuate portion 104a and the second arcuate portion 104b may be elastically deformable. Therefore, a counter force 142a, 142b is generated when the respective portion 104a, 104b is deflected out of its corresponding resting position 140a, 140b. Although the angles of deflection are illustratively depicted as being towards housing 102, other angles of deflection are possible. In some aspects, the angle of deflection from 140a may be different than the angle of deflection from 140b with respect to the longitudinal axis of the housing 102. Illustratively, the shape of the pins 104 of the connector 100 allows an elastic deformation of the pins so that, for example, a spring-loaded contact can be formed with a corresponding set of boards to be connected via the connector 100.

FIG. 2 illustrates a pin 200 in a schematic view, according to various aspects. The pin 200 may be used as the pins 104 described with reference to the connector 100. According to various aspects, the pin 200 may be curved (e.g., arch-shaped). Illustratively, the pin 200 may have a C-shape (or substantially a C-shape) or a U-shape (or substantially a U-shape). In some aspects, the pin 200 may have a plurality of elongated portions 200p extending (e.g., substantially) along a curved line 201.

It has to be understood that a curved line may be approximated, for example, via a suitable polygonal chain. Therefore, the term “curved line” as used herein may be understood as a line that has substantially a curved shape.

In some aspects, the pin 200 may include a plurality of elongated portions 200p that may be arranged relative to one another in such a way that the pin 200 has a curved (e.g., bent, arched, bowed, among others) shape. In some aspects, the pin 200 may have a multi-angled shape. However, the pin 200 may be free of sharp kinks. The elongated portions 200p of the pin 200 that are adjacent to one another may be elongated into the same direction (or substantially the same direction), e.g., the deviation of the change of the elongation direction from one linearly elongated portion to the adjacent linearly elongated portion may be less than 50°. In some aspects, the pin 200 may have a multi-angle shape such that each of the angles of the multi-angle shape are greater than a predetermined angle (e.g., 40°, e.g., 45°, e.g., 50°).

In some aspects, the pin 200 may have a first contact region 202a and a second contact region 202b disposed at opposite sides of the pin 200. The first contact region 202a may have a first contact surface 204a facing away from the pin 200 and the second contact region 202b may having a second contact surface (not shown in FIG. 2) facing away from the pin 200. In some aspects, the first contact surface 204a may be parallel (or substantially parallel) to the second contact surface.

FIG. 3A illustrates a connector 300 in a schematic view, according to various aspects. The connector 300 may include a housing 102 and a plurality of pins 104. The housing 102 and the plurality of pins 104 may be configured in the same or a similar way as described above with reference to FIG. 1A, FIG. 1B, FIG. 1C, and/or FIG. 2 and vice versa.

According to various aspects, the housing 102 may include a mounting structure 302. The mounting structure 302 may define a mounting position of the connector 300 relative to a contact structure associated with the connector 300.

According to various aspects, each of the pins 104 of the connector 300 may provide two contact surfaces at opposite sides of the housing 102. On each side of the housing 102, the contact surfaces define a contact layout. The contact regions of the pins 104 may be also referred to as landing pads. The landing pads may provide the electrical contact to a corresponding contact structure, e.g., to a contact structure of a board.

FIG. 3B illustrates a layout of the landing pads 304 (e.g., the contact surfaces and/or contact regions) of the plurality of pins 104 of a connector in a schematic view, according to various aspects. According to various aspects, the surface area of the landing pads 304 may be less than about 1 mm². Each landing pad 304 may have a length 304a in the range from about 0.5 mm to about 1 mm. Each landing pad 304 may have a width 304b in the range from about 0.2 mm to about 0.6 mm. According to various aspects, the landing pad 304 may be elongated, e.g., may have a length 304a that is greater than the width 304b. The length 304a may be, for example, greater than 150% of the width 304b.

As illustrated in FIG. 3A and FIG. 3B, the pins 104 (and the landing pads 304) may be aligned regularly, e.g., may have a fixed spacing in x-direction and/or a fixed spacing in y-direction. The housing 102 may be elongated along the x-direction, e.g., the housing 102 may have a length (in x-direction) in the range from about 1 cm to about 10 cm. The width of the housing 102 (in y-direction perpendicular to the x-direction) may be in the range from about 1 mm to about 20 mm. The height of the housing 102 (in z-direction perpendicular to the x-direction and the y-direction) may be in the range from about 0.2 mm to about 1 mm. As illustrated in FIG. 3A, the housing 102 may have a bar-shape.

According to some aspects, all of the landing pads 304 of the connector 300 may be elongated along the same elongation direction 304d. In some aspects, the elongation direction 304d may be angled with respect to the outer edges of the housing 102, e.g., the elongation direction 304d may be angled with respect to a first outer edge 302x of the housing 102 extending along the x-direction and with respect to a second outer edge 302y of the housing 102 extending along the y-direction. In some aspects, the angle between the x-y-directions and the elongation direction 304d may be in the range from about 30° to about 60°.

FIG. 3C illustrates a section of the connector 300 in a view schematic view, according to various aspects. The contact regions and, therefore, the landing pads 304 are spaced apart from the housing 102. In other words, a gap 306 may be disposed between the respective end-portions of the pins 104 and the housing 102. The gap 306 may have a gap-height 306h in the range from about 0.1 to about 1 mm, e.g., in the range from about 0.2 to about 0.5 mm.

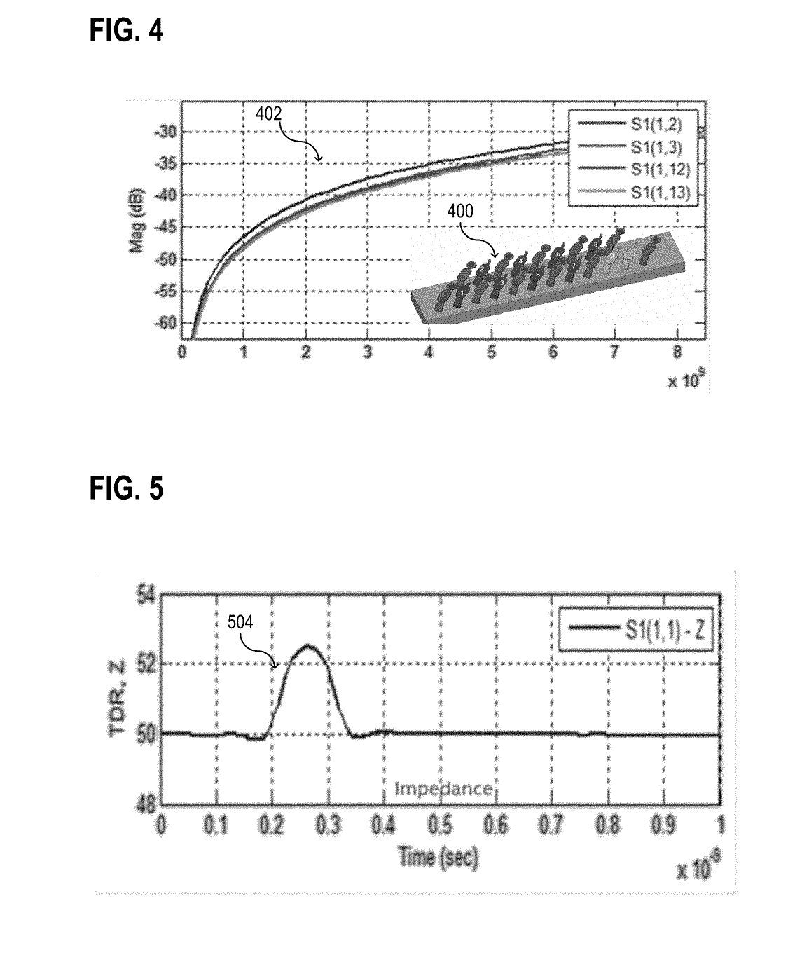

FIG. 4 illustrates a crosstalk behavior 402 of a connector 400 having a pin design as described herein. The magnitude of the crosstalk is depicted on the vertical axis (in dB) and the frequency dependence is depicted on the horizontal axis. The crosstalk behavior 402 is depicted with respect to four different pairs of pins (1, 2), (1, 3), (1, 12), and (1, 13).

FIG. 5 illustrates a corresponding TDR (Time Domain Reflectometry) characteristic 504. The height of the pulse signal is depicted on the vertical axis being a function of the impedance (Z). The time is depicted on the horizontal axis.

FIG. 6 illustrates a memory module 600 in a schematic view, according to various aspects. The memory module 600 may include any type of DRAM (Dynamic Random Access Memory) module. However, other types of memory modules may be used in a similar way. The memory module 600 may include a module pin array 600c (e.g., including 288 pins or more than 288 pins). The module pin array 600c allows addressing the memory cells 600m of the memory module 600 when the memory module 600 is inserted into a corresponding slot. For example, the memory module 600 may be inserted into a corresponding (memory) slot of a (e.g., system) board of a computing system.

According to various aspects, the memory module 600 may be used as a carrier board to host one or more additional (mezzanine) boards. The memory module 600 may include or may be associated with one or more connectors 602 disposed at least at one side of the memory module 600. Each of the connectors 602 of the memory module 600 may be configured as described herein, e.g., with respect to the connector 100 illustrated in FIGS. 1A to 1C or to the connector 300 illustrated in FIGS. 3A to 3C. FIG. 6 includes a detailed view of a pin layout of such a connector 602.

FIG. 7 illustrates a pin layout of a connector 700 in a schematic view, according to various aspects. In this case, the connector 700 may include plurality of pins 104 (as described herein) that may be arranged in an array similar to a BGA (Ball Grid Array) socket. Although the FIG. 7 illustrates one specific particular pin layout, other configurations are contemplated by the present disclosure. For instance, the number of pins and their respective orientation may be adapted to the address a variety of board configurations.

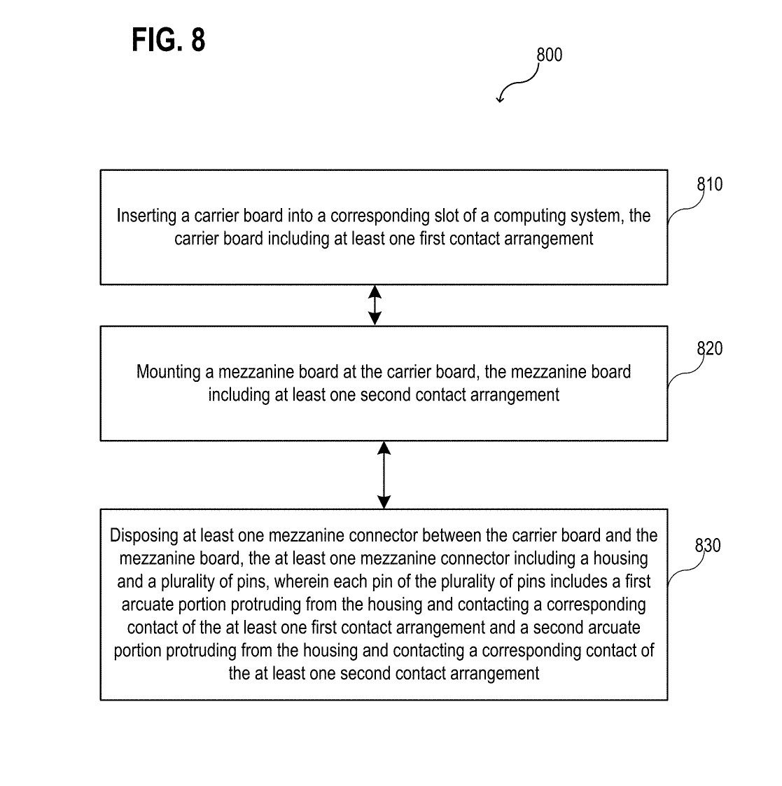

FIG. 8 shows a schematic flow diagram of a method 800 for mounting a board assembly, according to various aspects. The connector having the plurality of pins 104 as described herein may be used as a mezzanine connector to connect a mezzanine board with its corresponding carrier board.

According to various aspects, the method 800 may include: in 810, inserting a carrier board into a corresponding slot of a computing system, the carrier board including at least one first contact arrangement; in 820, mounting a mezzanine board at the carrier board in a parallel arrangement (or substantially parallel), the mezzanine board including at least one second contact arrangement; and, in 830, disposing at least one mezzanine connector between the carrier board and the mezzanine board, the at least one mezzanine connector including a housing and a plurality of pins, wherein each pin of the plurality of pins includes a first arcuate portion protruding from the housing and contacting a corresponding contact of the at least one first contact arrangement and a second arcuate portion protruding from the housing and contacting a corresponding contact of the at least one second contact arrangement. According to various aspects, the mezzanine board may be mounted (e.g., fixed via one or more screws) to the carrier board so that the mezzanine board and the carrier board are arranged parallel (or substantially parallel) to one another.

As described in accordance with some aspects, the pins 104 of the connector may be flexible in terms of elastic deformation. Therefore, the at least one mezzanine connector may be disposed between the carrier board and the mezzanine board so that a first spring-loaded contact is formed via the plurality of pins and the at least one first contact arrangement and so that a second spring-loaded contact is formed via the plurality of pins and the at least one second contact arrangement. In this case, the first spring-loaded contact and the second spring-loaded contact are formed via deflecting each pin of the plurality of pins out of its corresponding resting position.

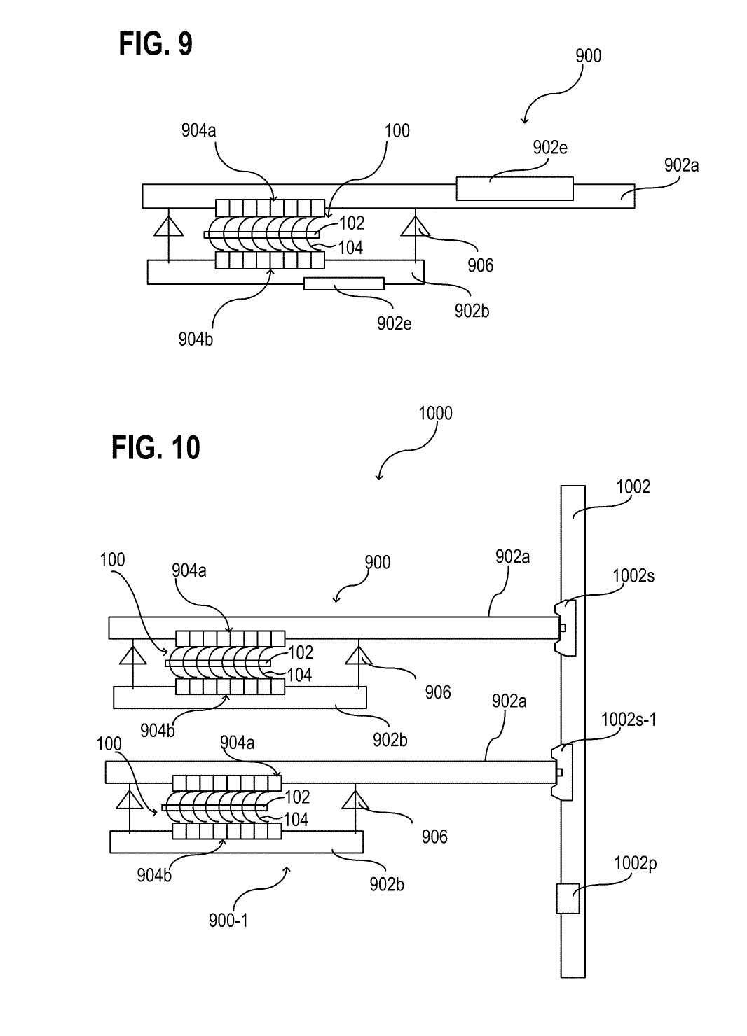

FIG. 9 shows a board assembly 900 in a schematic view, according to various aspects. The board assembly 900 may include a first board 902a having at least one first contact arrangement 904a and a second board 902b having at least one second contact arrangement 904b. Further, the board assembly 900 may include at least one connector 100 disposed between the first board 902a and the second board 902b. The at least one connector 100 of the board assembly 900 may be configured as described herein, e.g., with reference to connector 100 described in FIGS. 1A to 1C, among others

The at least one connector 100 of the board assembly 900 may include a housing 102 and a plurality of pins 104, wherein each pin of the plurality of pins 104 includes a first portion protruding arcuately from the housing 102 and contacting a corresponding contact of the at least one first contact arrangement 904a and a second portion protruding arcuately from the housing 102 and contacting a corresponding contact of the at least one second contact arrangement 904b.

According to various aspects, the first board 902a may be a printed circuit board. However, any other suitable carrier used in computer technology may be used in a similar way. According to various aspects, the second board 902b may be a printed circuit board. However, any other suitable carrier used in computer technology may be used in a similar way.

According to various aspects, the first board 902a and the second board 902b may include one or more electronic components 902e. The electronic components 902e may include one or more of the following components: a volatile memory; a non-volatile memory; an input/output interface; an analog-to-digital converter; a digital-to-analog converter; a graphic processor; a logic processor; among others

According to various aspects, the first contact arrangement 904a may include a plurality of contact pads forming a first contact pad array and the second contact arrangement 904b may include a plurality of contact pads forming a second contact pad array. In accordance with the contact pad arrays, the plurality of pins 104 of the at least one connector 100 may form a pin array to connect predefined pairs of contact pads of the two contact pad arrays with one another.

In some aspects, the first contact arrangement 904a may have the same contact layout (e.g., the same number of contact pads, the same spacing) as the second contact arrangement 904b.

As illustrated in FIG. 9, the connector 100 may be a single piece connector. Each pin of the plurality of pins 104 may be in direct physical contact with the corresponding contact pads of both contact arrangements 904a, 904b.

As described in accordance with some aspects, the pins 104 of the connector 100 may be flexible in terms of elastic deformation. Therefore, the at least one connector 100 may be disposed between the first board 902a and the second board 902b so that a first spring-loaded contact is formed via the plurality of pins 104 and the at least one first contact arrangement 904a and so that a second spring-loaded contact is formed via the plurality of pins 104 and the at least one second contact arrangement 904b. In this case, the first spring-loaded contact and the second spring-loaded contact are formed via deflecting each pin of the plurality of pins 104 out of its corresponding resting position (see FIG. 1C).

According to some aspects, the first board 902a and the second board 902b may have each a planar shape and the two boards 902a, 902b may be aligned in parallel (or substantially parallel) with one another. Further, the second board 902b may be mounted to the first board 902a via at least one mounting structure 906.

According to various aspects, the first board 902a may be a carrier board and the second board 902b may be a mezzanine board.

FIG. 10 shows a computing system 1000 in a schematic view, according to various aspects. According to various aspects, the computing system 1000 may include a system board 1002 and a board assembly 900. The board assembly 900 may include a first board 902a having at least one first contact arrangement 904a, a second board 902b having at least one second contact arrangement 904b, and at least one connector 100 disposed between the first board 902a and the second board 902b to connect the at least one first contact arrangement 904a with the at least one second contact arrangement 904b, as described herein.

According to various aspects, the system board 1002 may include at least one slot 1002s configured to host (e.g., to receive and connect) the first board 902a of the board assembly 900. The first board 902a may be a carrier board configured to host at least one mezzanine board. The second board 902b may be a mezzanine board mounted to the first board (the carrier board) 902a.

As illustrated in FIG. 10, the system board 1002 of the computing system may include one or more additional slots 1002s-1 to host one or more additional boards. As an example, the computing system 1000 may include at least one additional board assembly 900-1. The respective additional board assembly 900-1 may be similar to the board assembly 900. In this case, the respective carrier board 902a of the one or more additional board assemblies 900-1 may be inserted into the one or more additional slots 1002s-1 of the system board 1002.

In some aspects, the mezzanine board 902b of the respective board assembly may not be directly connected to a slot of the system board. Instead, the mezzanine board 902b may be mounted at the corresponding carrier board 902a and may be connected via the respective connectors 100.

According to various aspects, the system board 1002 may include one or more processors 1002p. The carrier board 902a may be communicatively coupled with the one or more processors 1002p via the respective slot 1002s. The mezzanine board 902b may be communicatively coupled with the one or more processors 1002p via the carrier board 902a.

In the following, various examples are provided with reference to the aspects described above.

Example 1 is a connector, including: a housing including a first housing surface at a first side of the housing and a second housing surface at a second side of the housing, wherein the first housing surface is opposite to the second housing surface and/or wherein the first side of the housing is opposite to the second side of the housing; and a plurality of pins, wherein each pin of the plurality of pins includes a first portion protruding arcuately from the first housing surface and a second portion protruding arcuately from the second housing surface.

In Example 2, the connector of Example 1 may further include that the connector is a board-to-board connector, e.g. a printed circuit board to printed circuit board connector.

In Example 3, the connector of Examples 1 or 2 may further include that each pin of the plurality of pins includes a first contact region at the first side and a second contact region at the second side.

In Example 4, the connector of any one of Examples 1 to 3 may further include that the housing has (e.g., substantially) a bar-shape.

In Example 5, the connector of any one of Examples 1 to 4 may further include that the housing includes the first housing surface at the first side of the housing and the second housing surface at the second side of the housing, wherein the first housing surface is substantially parallel to the second housing surface.

In Example 6, the connector of Example 5 may further include that a dimension of the housing perpendicular to the first and second housing surface is less than about 1 mm.

In Example 7, the connector of Examples 5 or 6 may further include that a dimension of the respective pins of the plurality of pins perpendicular to the first housing surface and second housing surface is less than about 2 mm.

In Example 8, the connector of any one of Examples 5 to 7 may further include that an end-portion of the first portion is elongated substantially parallel to the first housing surface; and that an end-portion of the second portion is elongated substantially parallel to the second housing surface.

In Example 9, the connector of any one of Examples 5 to 8 may further include that a first segment of the first portion is elongated along a first direction and that a second segment of the first portion is elongated along a second direction different from the first direction; and that a first segment of the second portion is elongated along a third direction and that a second segment of the second portion is elongated along a fourth direction different from the third direction.

In Example 10, the connector of Example 9 may further include that a third segment of the first portion is elongated along a fifth direction different from both the first direction and the second direction; and that a third segment of the second portion is elongated along a sixth direction different from both the third direction and the fourth direction.

In Example 11, the connector of any one of Examples 1 to 10 may further include that each pin of the plurality of pins includes a first contact surface at the first side and a second contact surface at the second side, wherein the first contact surface is substantially parallel to the second contact surface.

In Example 12, the connector of any one of Examples 1 to 4 may further include that the first housing surface is substantially parallel to the second housing surface. Further, each pin of the plurality of pins may include a first contact surface at the first side and a second contact surface at the second side. Further, the first contact surface and the second contact surface may be substantially parallel to the first housing surface and the second housing surface, respectively.

In Example 13, the connector of Example 12 may further include that each of the first contact surfaces of the plurality of pins are parallel to one another, and that each of the second contact surfaces of the plurality of pins are parallel to one another.

In Example 14, the connector of Example 12 or 13 may further include that each of the first contact surfaces of the plurality of pins lie in a first common plane and that each of the second contact surfaces of the plurality of pins lie in a second common plane.

In Example 15, the connector of Example 14 may further include that the first common plane is parallel to the second common plane.

In Example 16, the connector of any one of Examples 1 to 15 may further include that the first portion and the second portion are elastically deformable.

In Example 17, the connector of Example 16 may further include that the first portion is configured to provide a first counter force when deflected from a resting position of the first portion; and

In Example 18, the connector of Examples 16 or 17 may further include that the second portion is configured to provide a second counter force when deflected from a resting position of the second portion;

In Example 19, the connector of any one of Examples 1 to 18 may further include that the plurality of pins define a pin array having a pin density of equal to or greater than about 50 pins per square centimeter.

In Example 20, the connector of any one of Examples 1 to 19 may further include that each pin of the plurality of pins has a c-shape or a u-shape.

In Example 21, the connector of any one of Examples 1 to 20 may further include that the housing includes a mold material.

In Example 22, the connector of any one of Examples 1 to 21 may further include that the housing includes at least one mounting structure configured to define a mounting position of the connector relative to a contact structure associated with the connector.

In Example 23, the connector of any one of Examples 1 to 22 may further include that a single-ended near-end crosstalk between two adjacent pins of the plurality of pins is lower than about −15 decibels (dB) at a frequency of 9 gigahertz (GHz) and lower than −30 dB at a frequency of 2 GHz.

In Example 24, the connector of any one of Examples 1 to 23 may further include that a single-ended far-end crosstalk between two adjacent pins of the plurality of pins is lower than about −25 dB at a frequency of 9 GHz and lower than −40 dB at a frequency of 2 GHz.

Example 25 is a board assembly, including: a first board including at least one first contact arrangement; a second board including at least one second contact arrangement; and at least one connector according to any one of Examples 1 to 24, wherein the at least one connector is disposed between the first board and the second board, and wherein the at least one connector is configured to electrically connect the at least one first contact arrangement with the at least one second contact arrangement.

Example 26 is a board assembly, including: a first board including at least one first contact arrangement; a second board including at least one second contact arrangement; and at least one connector disposed between the first board and the second board, the at least one connector including a housing and a plurality of pins, wherein each pin of the plurality of pins includes a first portion protruding arcuately from the housing and contacting a corresponding contact of the at least one first contact arrangement and a second portion protruding arcuately from the housing and contacting a corresponding contact of the at least one second contact arrangement.

In Example 27, the board assembly of Example 26 may further include that the first board is a printed circuit board and/or wherein second board is a printed circuit board.

In Example 28, the board assembly of Examples 26 or 27 may further include that the first board includes at least one of the following components: a volatile memory; a non-volatile memory; an input/output interface; an analog-to-digital converter; a digital-to-analog converter; a graphic processor; or a logic processor.

In Example 29, the board assembly of Example 28 may further include that the second board includes at least one of the following components: a volatile memory; a non-volatile memory; an input/output interface; an analog-to-digital converter; a digital-to-analog converter; a graphic processor; or a logic processor.

In Example 30, the board assembly of any one of Examples 26 to 29 may further include that each of the at least one first contact arrangement includes a plurality of contact pads forming a first contact pad array and that each of the at least one second contact arrangement includes a plurality of contact pads forming a second contact pad array; and that the plurality of pins of the at least one connector defines a pin array in accordance with both the first contact pad array and the second contact pad array.

In Example 31, the board assembly of any one of Examples 26 to 30 may further include that each of the at least one first contact arrangement has the same contact layout as each of the at least one second contact arrangement.

In Example 32, the board assembly of any one of Examples 26 to 31 may further include that the connector is a single piece connector.

In Example 33, the board assembly of any one of Examples 26 to 32 may further include that the plurality of pins of the connector and the at least one first contact arrangement form a first spring-loaded contact and/or that the plurality of pins of the connector and the at least one second contact arrangement form a second spring-loaded contact.

In Example 34, the board assembly of any one of Examples 26 to 33 may further include that the first board and the second board have a planar shape and are substantially in parallel with one another.

In Example 35, the board assembly of any one of Examples 26 to 34 may further include at least one mounting structure configured to couple the second board to the first board.

In Example 36, the board assembly of any one of Examples 26 to 35 may further include that the first board is carrier board and that the second board is a mezzanine board.

Example 37 is a computing system, including: a system board including one or more slots configured to host one or more boards; a carrier board hosted in a slot of the one or more slots; a mezzanine board; and one or more connectors according to any one of Examples 1 to 24 configured to electrically connect the mezzanine board to the carrier board.

Example 38 is a computing system, including: a system board including one or more slots configured to host one or more boards; a carrier board hosted in a slot of the one or more slots; a mezzanine board; and one or more connectors configured to electrically connect the mezzanine board to the carrier board, each connector of the one or more connectors including a housing and a plurality of pins, wherein each pin of the plurality of pins includes a first portion protruding arcuately from the housing, which is configured to contact a corresponding contact of at least one contact arrangement of the mezzanine board and a second portion protruding arcuately from the housing, which is configured to contact a corresponding contact of at least one contact arrangement of the carrier board.

In Example 39, the computing system of Example 38 may further include at least one mounting structure configured to couple the mezzanine board to the carrier board.

Example 40 is a method for mounting a board assembly, the method including: inserting a carrier board into a corresponding slot of a computing system, the carrier board including at least one first contact arrangement; mounting a mezzanine board at the carrier board, the mezzanine board including at least one second contact arrangement; and disposing at least one mezzanine connector between the carrier board and the mezzanine board, the at least one mezzanine connector including a housing and a plurality of pins, wherein each pin of the plurality of pins includes a first portion protruding arcuately from the housing and contacting a corresponding contact of the at least one first contact arrangement and a second portion protruding arcuately from the housing and contacting a corresponding contact of the at least one second contact arrangement.

In Example 41, the method of Example 40 may further include that the mezzanine board is mounted in parallel with the carrier board.

In Example 42, the method of Example 40 or 41 may further include that disposing the at least one mezzanine connector between the carrier board and the mezzanine board includes: forming a first spring-loaded contact via the plurality of pins and the at least one first contact arrangement; and forming a second spring-loaded contact via the plurality of pins and the at least one second contact arrangement.

In Example 43, the method of Example 42 may further include that forming the first spring-loaded contact and the second spring-loaded contact includes deflecting each pin of the plurality of pins from a respective resting position thereof.

While the disclosure has been particularly shown and described with reference to specific aspects, it should be understood by those skilled in the art that various changes in form and detail may be made therein without departing from the spirit and scope of the disclosure as defined by the appended claims. The scope of the disclosure is thus indicated by the appended claims and all changes, which come within the meaning and range of equivalency of the claims, are therefore intended to be embraced.

What is claimed is:

1. A connector, comprising:
a housing comprising a first housing surface at a first side of the housing and a second housing surface at a second side of the housing, wherein the first side is opposite to the second side; and
a plurality of pins, wherein each pin of the plurality of pins comprises a first portion protruding arcuately from the first housing surface and a second portion protruding arcuately from the second housing surface.

2. The connector of claim 1,
wherein the connector is a board-to-board connector.

3. The connector of claim 1,
wherein the housing has a bar-shape.

4. The connector of claim 1,
wherein a dimension of the respective pins of the plurality of pins perpendicular to the first housing surface and the second housing surface is less than about 2 mm.

5. The connector of claim 1,
wherein an end-portion of the first portion is elongated substantially parallel to the first housing surface; and
wherein an end-portion of the second portion is elongated substantially parallel to the second housing surface.

6. The connector of claim 1,
wherein a first segment of the first portion is elongated along a first direction and a wherein second segment of the first portion is elongated along a second direction different from the first direction; and
wherein a first segment of the second portion is elongated along a third direction and a wherein second segment of the second portion is elongated along a fourth direction different from the third direction.

7. The connector of claim 6,
wherein a third segment of the first portion is elongated along a fifth direction different from both the first direction and the second direction; and
wherein a third segment of the second portion is elongated along a sixth direction different from both the third direction and the fourth direction.

8. The connector of claim 1,
wherein each pin of the plurality of pins comprises a first contact surface at the first side and a second contact surface at the second side, wherein the first contact surface is substantially parallel to the second contact surface.

9. The connector of claim 8,
wherein the first contact surface and second contact surface are substantially parallel to the first housing surface and the second housing surface, respectively.

10. The connector of claim 8,
wherein each of the first contact surfaces of the plurality of pins are parallel to one another; and
wherein each of the second contact surfaces of the plurality of pins are parallel to one another.

11. The connector of claim 8,
wherein each of the first contact surfaces of the plurality of pins lie in a first common plane; and
wherein each of the second contact surfaces of the plurality of pins lie in a second common plane.

12. The connector of claim 11,
wherein the first common plane is parallel to the second common plane.

13. The connector of claim 1,
wherein the first portion and the second portion are elastically deformable;
wherein the first portion is configured to provide a first counter force when deflected from a resting position of the first portion; and
wherein the second portion is configured to provide a second counter force when deflected from a resting position of the second portion.

14. The connector of claim 1,
wherein the plurality of pins define a pin array having a pin density of equal to or greater than about 50 pins per square centimeter.

15. The connector of claim 1,
wherein the housing comprises a mold material.

16. A board assembly, comprising:
a first board comprising at least one first contact arrangement;
a second board comprising at least one second contact arrangement; and
at least one connector disposed between the first board and the second board, the at least one connector comprising a housing and a plurality of pins, wherein each pin of the plurality of pins comprises a first portion protruding arcuately from the housing and contacting a corresponding contact of the at least one first contact arrangement and a second portion protruding arcuately from the housing and contacting a corresponding contact of the at least one second contact arrangement.

17. The board assembly of claim 16,
wherein each of the at least one first contact arrangement comprises a plurality of contact pads forming a first contact pad array and wherein each of the at least one second contact arrangement comprises a plurality of contact pads forming a second contact pad array; and
wherein the plurality of pins of the at least one connector defines a pin array in accordance with both the first contact pad array and the second contact pad array.

18. The board assembly of claim 16,
wherein the plurality of pins of the connector and the at least one first contact arrangement form a first spring-loaded contact and/or
wherein the plurality of pins of the connector and the at least one second contact arrangement form a second spring-loaded contact.

19. A method for mounting a board assembly, the method comprising:
inserting a carrier board into a corresponding slot of a computing system, the carrier board comprising at least one first contact arrangement;
mounting a mezzanine board at the carrier board, the mezzanine board comprising at least one second contact arrangement; and
disposing at least one mezzanine connector between the carrier board and the mezzanine board, the at least one mezzanine connector comprising a housing and a plurality of pins, wherein each pin of the plurality of pins comprises a first portion protruding arcuately from the housing and contacting a corresponding contact of the at least one first contact arrangement and a second portion protruding arcuately from the housing and contacting a corresponding contact of the at least one second contact arrangement.

20. The method of claim 19,
wherein disposing the at least one mezzanine connector between the carrier board and the mezzanine board comprises:
forming a first spring-loaded contact via the plurality of pins and the at least one first contact arrangement; and
forming a second spring-loaded contact via the plurality of pins and the at least one second contact arrangement.
